(19) United States
(12) Patent Application Publication
(10) Pub. No.: US 2008/0094918 A1
(43) Pub. Date: Apr. 24, 2008

(54) Memory read control circuit and control method thereof

(75) Inventor: Hideaki Fujizoe, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/905,826

(22) Filed: Oct. 4, 2007

(30) Foreign Application Priority Data
Oct. 18, 2006 (JP) 2006-284060

(51) Int. Cl. G11C 7/00; G11C 7/06

(52) U.S. Cl. 365/189.07; 365/189.11; 365/193

(57) ABSTRACT

A control circuit to which a read requirement signal for data read of a memory and a burst length information signal for the read requirement are input controls a pull-up circuit so as to pull-up a data strobe signal if the read requirement signal is active. A mask signal is made to an unmask state if the data strobe signal is transferred from H-level to L-level. The mask signal is made to an unmask state if a repetition of the predetermined transfer of the data strobe signal is detected based on the burst length information signal. A postamble in the data strobe signal starts by the repetition of the transfer, and after the end of the postamble period, the data strobe signal is pulled-up to H-level.

### REFERENCE TO RELATED APPLICATION

This application is based upon and claims the benefit of the priority of Japanese patent application No. 2006-284060, filed on Oct. 18, 2006, the disclosure of which is incorporated herein in its entirety by reference thereto.

### FIELD OF THE INVENTION

This invention relates to a memory read control circuit and control method thereof, and, in particular, the memory read control circuit for reading out data from a DDR SDRAM (Double Data Rate Synchronous Dynamic Random Access Memory) and control method thereof.

### BACKGROUND OF THE INVENTION

The DDR SDRAM is an SDRAM having a high speed data transfer function, which can reads and writes data at both of start and end of a clock signal for synchronizing between circuits. The DDR SDRAM has the narrower width of a determined data than SDR SDRAM (Single Data Rate Synchronous Dynamic Random Access Memory) since the DDR SDRAM inputs and outputs data at twice frequency as an outside clock. If the lengths of wirings between a memory and a controller are different, the difference in a time (a flight time) to reach data to a receiver makes difficult to determine the timing at which the receiver receives data. Thus, the DDR SDRAM uses a data strobe signal (DQS) in order to notify the timing for the data transfer of the receiver. The DQS is a bidirectional strobe signal and functions as an operational standard clock in the data-input and output of the read/write operation. In the read operation, the edges between the DQS and the read data are matched. So, when the read data is received from the DDR SDRAM, the received DQS is delayed in the inside until the center of the read data.

The data strobe signal DQS is transferred from high impedance (an intermediate level) to a low level when a read command (READ) is received in the state in which the DDR SDRAM is active. This period at the low level is a preamble. The preamble generates by one clock earlier than before the first data is output. After the preamble, the data strobe signal DQS is toggled at the same frequency as the clock signal while the effective data is present on a data input and output terminal (DQ). The period at the low level after the last data is transferred is a postamble. The postamble is generated for about ½ clocks from the edge of the last data.

The data strobe signal DQS is transferred from the high impedance state to the preamble and from the postamble to the high impedance (the intermediate level). If the intermediate level is transferred into the memory interface as a signal of an unstable level, there is a possibility that the read data in a data receiving section is destroyed before the read data is latched at a data synchronous section. There are known technologies for attempting to prevent the unstable level from being transferred into an input side of the strobe signal so that such data does not become unstable (See Patent Documents 1 and 2, for example).

FIG. 5 is a block diagram showing a configuration of a data strobe receiver disclosed in Patent Document 1. In FIG. 5, the data strobe receiver comprises an input comparator 120 which compares a data strobe signal (DQS) with a reference voltage 117 (1st Vref). The data strobe receiver also comprises a comparator 135 that compares a reference voltage 132 (2nd Vref) whose comparison level is set higher or lower than the reference voltage 117 with the data strobe signal DQS. An output 140 (DQS_Detect) of the comparator 135 outputs a low level since, in an initial state, the data strobe signal DQS is at the intermediate level (high impedance). The output 140 is connected to an input Preset of a flip-flop 145. Preset is inactive since the low level is at input at the initial state. An output Q of the flip-flop 145 is at low-level because of reset by a Clear signal at the beginning. The output of the comparator 120 is input into a delay element 125. The delay element 125 can delay the input signal by 90 degree (in phase), outputs a 90 degree delay signal DQS_90 whose input is delayed by 90 degree only while an Enable signal is at high-level, into an FIFO 110, and makes the 90 degree delay signal DQS_90 into low-level for the period of the Enable signal being at low-level irrespective of the input. Since, at the initial state, the Enable signal is at low-level, the 90 degree delay signal DQS_90 is at low-level.

When the data transfer starts, although the data strobe signal DQS is transferred from the intermediate level to the low level, DQS_Detect remains at low-level and Enable also remains at low-level since the signal level of the data strobe signal DQS is lower than an electrical potential of the 2nd Vref even in this state. Then, the data strobe signal DQS is transferred to the high level, the comparator 135 detects the high level, and DQS_Detect is transferred to the high level. Since at this time the flip-flop 145 assumes a Preset state, the Enable signal becomes high-level. Therefore, the output of the 90 degree delay signal DQS_90 starts. The 90 degree delay signal DQS_90 is inverted by an inverter 155, the inverted signal being connected to a clock input of the flip-flop 145, the data input (low-level) of the flip-flop 145 being latched by the transfer of the 90 degree delay signal DQS_90 to low-level. This makes Enable of the delay element 125 low-level. The data strobe signal is transferred to the high level again, DQS_Detect is transferred to the high level, and Enable is transferred to the high level. Thus, this enables the output to the 90 degree delay signal DQS_90. This operation is repeated thereafter. FIFO 110 operates so as to receive the comparison result between the data signal DQ and the reference voltage 102 (3rd Vref) by a comparator 105 at every transfer of the 90 degree delay signal DQS_90. When the read access is finished, although the data strobe signal DQS is transferred to the intermediate-level (HiZ) state after the postamble, this transfer is disregarded since the intermediate level is lower than the level of the 2nd Vref.

FIG. 7 is a circuit diagram showing a general configuration of a memory interface control circuit according to the teaching of Patent Document 2. In FIG. 7, a variable delay circuit 204 is provided to execute a control of shifting the phase of a data strobe signal DQS, buffered in a buffer 202, by a half cycle of a clock. A mask generation circuit 205 generates a mask signal DQE from a basic mask signal SDF whose delay is modulated by the variable delay circuit 203, and a data strobe signal DQSL whose delay is modulated by the variable delay circuit 204. An AND circuit 206 performs a logical AND operation between the mask signal DQE generated by the mask generation circuit 205 and the data strobe signal DQSL, thereby generating a data strobe signal DQSP obtained by removing a glitch noise from the data strobe signal DQSL. A FIFO circuit 211 operates so as to output an output signal DOUT by receiving a data signal DQ buffered by a buffer 201 at every transfer of the data strobe signal DQSP. A control circuit 213 includes a function of generating a basic mask signal SDE whose delay is not modulated yet, a function of controlling the variable delay circuit 203, and a function of controlling the variable delay circuit 204, and further includes a function of generating a pattern for a calibration to a DDR2-SDRAM. The control circuit 213 makes a PASS/FAIL determination with the output signal DOUT having this pattern at a time of an initialization of the device as an expectation value and performs a calibration of delay times of the delay circuits 203, 204 so as to obtain the most suitable delay time.

### [Patent Document 1]

JP Patent Kokai Publication No. JP-P2003-223786A

### [Patent Document 2]

JP Patent Kokai Publication No. JP-P2005-276396A

### SUMMARY OF THE DISCLOSURE

In the data strobe receiver described in Patent Document 1, it is necessary to mount a comparator using 2nd Vref as a reference voltage so as not to detect the intermediate level of the data strobe signal DQS. Mounting the comparator in the chip increases the area of the chip. This increases the number of the circuits in the chip to provide 2nd Vref or of the components for an external supply resulting in increase in costs. Although 2nd Vref is set between the intermediate level and the high level or low level, the real wave form is supposed to have the disorder of the wave in each level because of the noise or reflection as shown in the ranges V1 and V2 of FIG. 6. Therefore, there is a possibility that it is difficult to modulate the level of 2nd Vref so as not to enter each level since the range for 2nd Vref is very narrow.

On the other hand, in the memory interface control circuit disclosed in Patent Document 2, although the data strobe signal DQSL is masked by the mask signal DQE output from the mask generation circuit 205, it is necessary to control the delay of the mask signal DQE by the variable delay circuit 203. The calibration to the DDR-SDRAM is necessary to control the delay of the variable delay circuit 203 to a most optimum value, which requires the control circuit 312 for the calibration. Also, it brings about a treating time for the calibration. Although the calibration is executed at the initialization of the device, there is possibility that the most optimum delay is not constant by the environmental variation, such as voltage variation and temperature variation, during the operation in practice. If the calibration be regularly executed in order to avoid this problem, the performance of the memory access becomes worse. Accordingly, there is much desired in art.

According to one aspect of the present invention, there is provided a memory read control circuit comprising: a pull-up circuit that pulls-up an input terminal which inputs a data strobe signal output from a memory, a comparator circuit that compares a signal level of the data strobe signal with a predetermined reference voltage, a mask circuit that masks an output signal which is a comparison result of the comparator circuit with a mask signal, a delay circuit that delays the output signal of the mask circuit and generating the data strobe signal having a timing to receive data output from the memory, and a control circuit. The control circuit receives a read requirement signal to require a data read from the memory and a burst length information signal indicating the length of a burst for the read requirement, wherein the control circuit controls the pull-up circuit so as to pull-up the data strobe signal to a first level if the read requirement signal is active, and makes the mask signal to an unmask state if the data strobe signal is transferred from the first level to a second level, and makes the mask signal to a mask state if a repetition of a predetermined transfer of the data strobe signal is detected based on the burst length information signal.

According to another aspect of the present invention, there is provided a method for controlling a memory read control circuit. The method comprises: providing a memory read control circuit comprising: a pull-up circuit for pulling-up an input terminal to input a data strobe signal output from a memory, a comparator circuit for comparing a signal level of the data strobe signal with a predetermined reference voltage, a mask circuit for masking an output signal which is the comparison result of the comparator circuit with a mask signal, and a delay circuit for delaying the output signal of the mask circuit and generating the data strobe signal having a timing to receive data output from the memory. The method further comprises the steps of: pulling-up the data strobe signal to a first level if a read requirement signal to require a data read from the memory is active; detecting a transfer of the data strobe signal from the first level to a second level; making the mask signal to an unmask state if the data strobe signal is transferred to the second level; detecting a repetition of a predetermined transfer of the data strobe signal based on a burst length information signal to be input, and making the mask signal to a mask state if the data strobe signal repeats the predetermined transfer.

The meritorious effects of the present invention are summarized as follows. According to the present invention, based on the read requirement signal and burst length information, the pull-up of the data strobe signal is controlled and the mask of the data strobe signal is controlled, thereby eliminating unstable operation of the system by the delay variation of the data strobe signal since the timing design becomes easy.

### BRIEF DESCRIPTIONS OF THE DRAWINGS

FIG. 1 is a block diagram showing a configuration of a memory read control circuit according to a first example of the present invention.

FIG. 2 is a timing chart showing an operation timing of a memory read control circuit according to a first example of the present invention.

FIG. 3 is a flowchart showing an operation of a memory read control circuit according to a second example of the present invention.

FIG. 4 is a timing chart showing an operation timing of a memory read control circuit according to a second example of the present invention.

FIG. 5 is a block diagram showing a configuration of a data strobe receiver according to Patent Document 1.

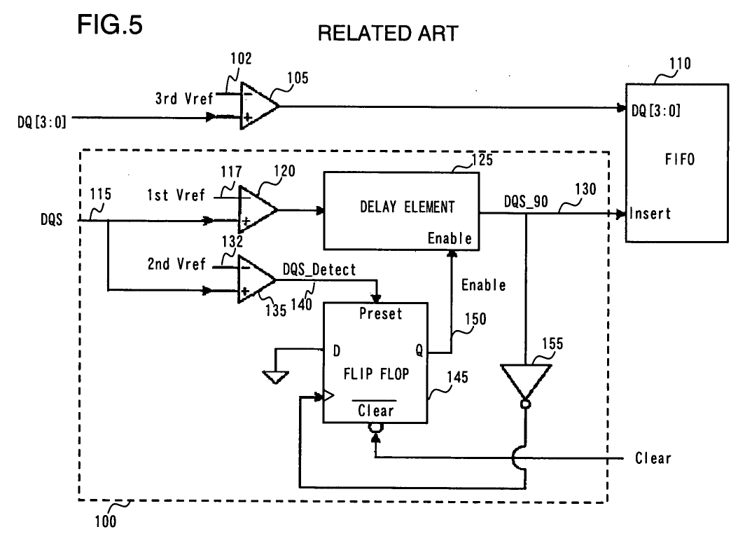

FIG. 6 is a figure showing a noise level schematically.

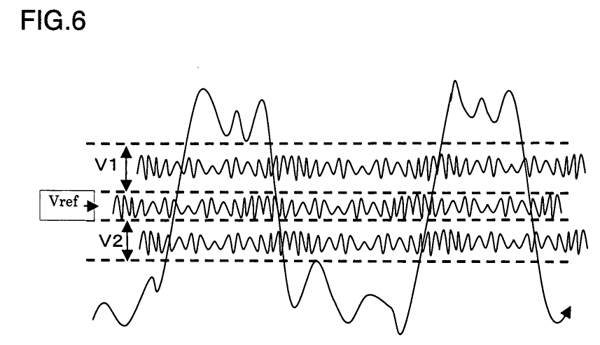

FIG. 7 is a block diagram showing a configuration of a memory interface control circuit according to the teaching of Patent Document 2.

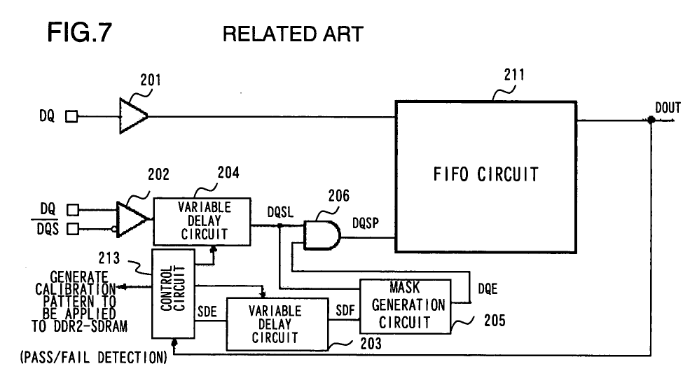

### PREFERRED MODES OF THE INVENTION

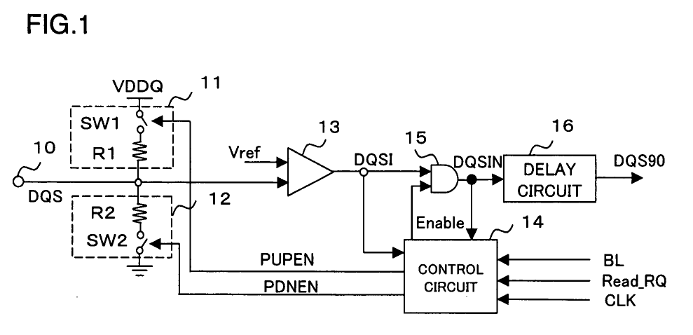

A memory read control circuit according to an exemplary embodiment of the present invention comprises a pull-up circuit (11 in FIG. 1) for pulling-up an input terminal (10 in FIG. 1) for inputting a data strobe signal (DQS in FIG. 1) output from a memory, a pull-down circuit (12 in FIG. 1) for pulling-down the input terminal (10 in FIG. 1), a comparator circuit (13 in FIG. 1) for comparing a signal level of the data strobe signal with a predetermined reference voltage (Vref in FIG. 1), a mask circuit (15 in FIG. 1) for masking an output signal which is a comparison result of the comparator circuit with a mask signal (Enable in FIG. 1), a delay circuit (16 in FIG. 1) for delaying the output signal of the mask circuit and generating a strobe signal (DQS90 in FIG. 1) having a timing for receiving data output from the memory, and a control circuit (14 in FIG. 1).

The control circuit receives a read requirement signal (Read_RQ in FIG. 1) for requiring a data read from the memory and a burst length information signal (BL in FIG. 1) indicating a burst length for the read requirement, controls the pull-up circuit so as to pull-up the data strobe signal to a first level (a high level, for example) if the read requirement signal becomes active, and makes the mask signal to an unmask state if the data strobe signal is transferred from the first level to a second level (a low level, for example), and the mask signal to a mask state if it is judged, based on the burst length information signal, whether the data strobe signal repeats the predetermined transfer indicating the read timing.

A postamble may start in the data strobe signal when the data strobe signal repeats the predetermined transfer, and the control circuit may finish the control to pull-up the data strobe signal to the first level after the postamble period ends.

The control circuit may also control the pull-down circuit to execute the operation if it is detected that the data strobe signal is transferred from the first level to the second level and to make the pull-down circuit to a non operative state synchronously with a timing at which the control to pull-up the data strobe signal to the first level is finished.

The control circuit may also make the mask signal to the mask state and subsequently make the mask signal to unmask state at a predetermined interval again if a new read requirement signal is input at the predetermined interval following the read requirement signal. The predetermined interval may correspond one clock cycle in the standard clock signal at which the control circuit is operated, signal repeats said predetermined transfer.

The method for controlling a memory read control circuit may further comprise: starting a postamble in the data strobe signal by repeating the predetermined transfer of the data strobe signal, and finishing the control to pull-up the data strobe signal to the first level after the end of the postamble period. The memory read control circuit may further comprise a pull-down circuit; and wherein the method may further comprise operating the pull-down circuit to pull-down the input terminal if the transfer of the data strobe signal from the first level to the second level is detected; and finishing the control to pull-up the data strobe signal to the first level and synchronously stopping the operation of the pull-down circuit.

The method may further comprise judging whether or not a new read requirement signal is consecutively input at a predetermined interval after the input of the read requirement signal; judging whether or not the data strobe signal is in the second level when the predetermined interval passes after the step of making the mask signal to the mask state if the new read requirement signal is consecutively input at the predetermined interval after the input of the read requirement signal; and making the mask signal to the unmask state again if the data strobe signal is in the second level.

As operated above, the control circuit transfers the data strobe signal (DQS) to the pull-up state during waiting for the read. Therefore, the transfer from the initial high impedance state (the intermediate level) to the low level at the beginning of the preamble of the data strobe signal (DQS) is changed to a transfer from the high level to the low level. Accordingly, the timing of the transfer becomes easy to be detected. Also, the control is carried out as follows: The mask of the data strobe signal (DQS) is released (ceased) at the beginning of the preamble, and the mask is started at the last falling edge of the data strobe signal (DQS). The data strobe signal (DQS90) without the glitch can thus be generated, and stable operation can be achieved since the conventional modulation of 2nd Vref is unnecessary. The present invention will be explained in detail referring to the drawings in line with examples.

### EXAMPLE 1

FIG. 1 is a block diagram showing a configuration of a memory read control circuit according to a first example of the present invention. In FIG. 1, a memory read control circuit comprises an input terminal 10, a pull-up circuit 11, a pull-down circuit 12, a comparator circuit 13, a control circuit 14, an AND circuit 15 and a delay circuit 16. The pull-up circuit 11 is a series connection circuit comprising a switch element SW1 controlled by a pull-up control signal PUPEN and a resistance element R1, with one end of the pull-up circuit 11 being connected with a power source VDDQ, the other end thereof being connected with the input terminal 10 of a data strobe signal DQS. The pull-down circuit 12 is a series connection circuit comprising a switch element SW2 controlled by a pull-down control signal PDNEN and a resistance element R2, with one end of the pull-down circuit 12 being connected with ground, the other end thereof being connected with the input terminal 10 of the data strobe signal DQS.

The comparator circuit 13 whose one input end is connected with the input terminal 10 functions as an input buffer, compares the signal level of the data strobe signal DQS with a reference voltage Vref of the other input end, and outputs a signal DQSI which is a comparison result to the control circuit 14 and the AND circuit 14. In the AND circuit 15, the signal DQSI is input to one input end, a mask signal Enable output from the control circuit 14 being input to the other input end, the signal DQSI is output as a signal DQSIN (an unmasked state) if the mask signal Enable is at H-level, the signal DQSIN remaining at L-level (a masked state) if the mask signal Enable is at L-level. The signal DQSIN which is the output of the AND circuit 15 is output to the control circuit 14 and delay circuit 16. The delay circuit 16 gives a time delay corresponding to 90 degree of the phase of a clock signal CLK to the signal DQSIN in the unmasked state and generates a strobe signal DQS90 having a timing for receiving data output from a memory. An explanation of a circuit for receiving a data signal by the strobe signal DQS90 is omitted since the circuit is similar to the conventional one.

The signal DQSI, the signal DQSIN, a read requirement signal Read_RQ which requires a data read from the memory, a burst length information signal BL which indicates a burst length for the read requirement, and the clock signal CLK are input to the control circuit 14. The control circuit 14 outputs the pull-up control signal PUPEN to the pull-up circuit 11 so that the data strobe signal DQS is pulled-up to the level of the power source VDDQ (H-level) if the read requirement signal Read_RQ is active (H-level). The read operation of the memory then starts, the preamble of the data strobe signal DQS being output from the memory, the data strobe signal DQS being transferred from the level of the power source VDDQ (H-level) to the level of the ground (L-level). This transfer turns the level of the mask signal Enable to H-level. The AND circuit 15 thus outputs the signal DQSI as the signal DQSIN (unmasked state). The repetition (the number of edges) of the predetermined transfer of the data strobe signal DQS for the data read timing is detected based on the burst length information signal BL, and the mask signal Enable is controlled to L-level (masked state).

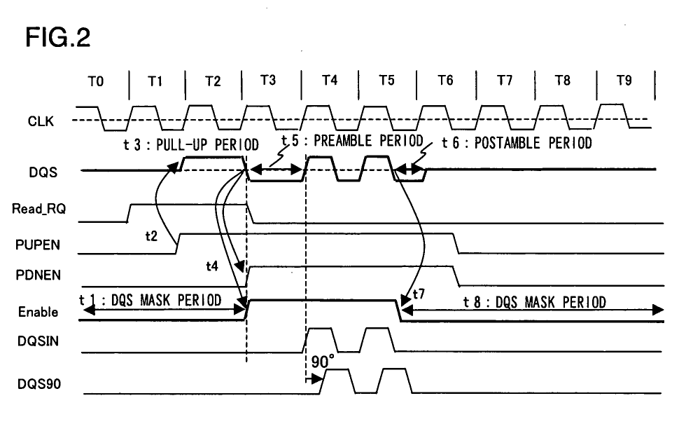

Next, an operation timing of the memory read control circuit will be explained. FIG. 2 is a timing chart showing an operation timing of the memory read control circuit according to the first example of the present invention. In FIG. 2, at the initial state (the T0 cycle), the mask signal Enable which is an output of the control circuit 14 is set to L-level, the output of the data strobe signal DQS to the delay circuit 16 being masked by the AND circuit 15 (DQS mask period t1).

The control circuit 14 outputs the pull-up control signal PUPEN of H-level at timing t2 (at the beginning of the cycle T2) and makes the pull-up circuit 11 to an On (active) state if the read requirement signal Read_RQ is transferred to H-level at the cycle T1. The data strobe signal DQS of the intermediate level is transferred to H-level by the pull-up (at the beginning of the pull-up period t3).

Thereafter, when the read operation of the memory starts, the data strobe signal DQS is transferred to L-level at timing t4 by the preamble (at the beginning of the preamble period t5). If the control circuit 14 detects the transfer of the data strobe signal DQS from H-level to L-level at the timing t4, the control circuit 14 releases (ceases) the masked state of the data strobe signal DQS by transferring the mask signal Enable to H-level, and starts the input of the data strobe signal DQS to the delay circuit 16. The control circuit 14 also transfers the pull-down control signal PDNEN to H-level at the same timing t4 to make both pull-up circuit 11 and pull-down circuit 12 to the active state, and starts a node terminal state at an ordinary VTT (VDDQ/2) level.

When the control circuit 14 finishes internally counting the edges of the data strobe signal DQS having a burst length of the read, the control circuit 14 judges that the postamble period t6 comes, and transfers the mask signal Enable to L-level (at the beginning of the DQS mask period t8) synchronously with the edge (end) of the data strobe signal DQS at the timing t7. The control circuit 14 may counts only the end of the data strobe signal DQS since the length of the burst in the read is n times as long as 2 (n is a natural number). If the length of the burst is 4, for example, the mask signal Enable may be transferred to L-level at the end of the second data strobe signal DQS. The data strobe signal DQS after the timing t7 thus is not conducted to the delay circuit 16 and assumes the masked state again (the DQS mask period t8). Accordingly, since the intermediate level or glitch after the postamble period t6 of the data strobe signal DQS is not propagated from the delay circuit 16 to the inside, the read data is prevented from being read at an unsuitable timing.

As operated above, the memory read control circuit unmasks the mask at the timing that the transfer in which the data strobe signal DQS is changed from H-level to L-level is detected at the beginning of the read. Since the beginning of the mask is synchronous with the data strobe signal DQS itself by counting the length of the burst in terms of the edges of the data strobe signal DQS, it is possible to reliably exclude the influence of the indefinite level which is the intermediate level of the data strobe signal DQS. It is also possible to operate the memory read control circuit without the influence of the delay of the signal seen from the clock signal CLK in the memory or interface and of fluctuation under certain conditions such as voltage or temperature change and a delay by a board wiring.

The timing of the input of the data strobe signal DQS at the read seen from the memory or interface suffers delay behind an ideal timing because of the following various factors.
(1) A delay of a clock which is supplied to the memory,
(2) a delay of communication of a clock and data strobe signal DQS on a PCB,
(3) a delay of the data strobe signal DQS output by the memory, and
(4) a delay in an interface circuit.

The delays of the above items (1)-(4) define a delay behind the standard (the clock signal) seen from the inside of the interface, and additionally they suffer fluctuations under various conditions, respectively. Therefore, it is difficult to receive only an effective period (not the intermediate level) of the data strobe signal DQS. Therefore, as is the case with the memory read control circuit according to this example, the unstable operation of the system caused by these fluctuations in the delay can be eliminated by controlling based on the data strobe signal DQS itself.

### EXAMPLE 2

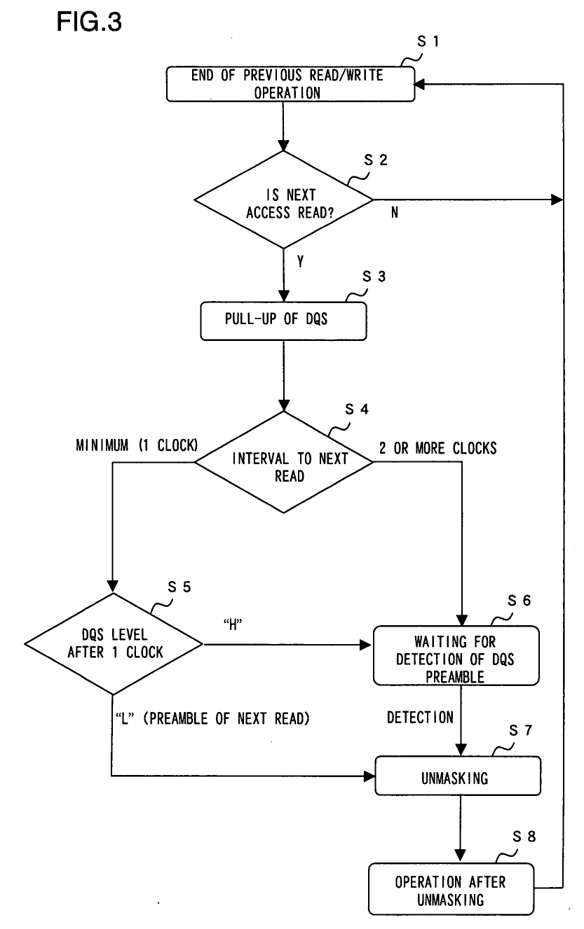

A configuration of a memory read control circuit according to a second example of the present invention is the same as FIG. 1. A part of the operation of the control circuit 14 is, however, different from Example 1. FIG. 3 is a flowchart showing an operation of a control circuit according to a second example of the present invention. In FIG. 3, the previous read cycle or write cycle is finished in step S1.

In step S2, whether or not next access is a read cycle is judged. If the read requirement signal Read_RQ is changed to H-level, in step S3, the data strobe signal DQS is made a pull-up state.

In step S4, whether the interval (period) to next read cycle is the minimum, 1 cycle, (corresponding to one cycle of the clock signal CLK) or 2 cycles or more, that is, whether or not the next read requirement signal Read_RQ follows after passing one or more cycle(s) of the clock signal CLK, is judged. If the interval to the read cycle is 2 cycles or more, waiting for the preamble in step S6, unmasking in step S7, and the operation after the unmasking in step S8 is performed as described in Example 1.

If the interval to the read cycle is 1 cycle, in step S5, it is determined whether or not the data strobe signal DQS after one clock from the beginning of the postamble is L-level or H-level. In case of H-level, the operation advances to step S6. In case of L-level, since this is a preamble in the next read cycle, unmasking is performed in step S7.

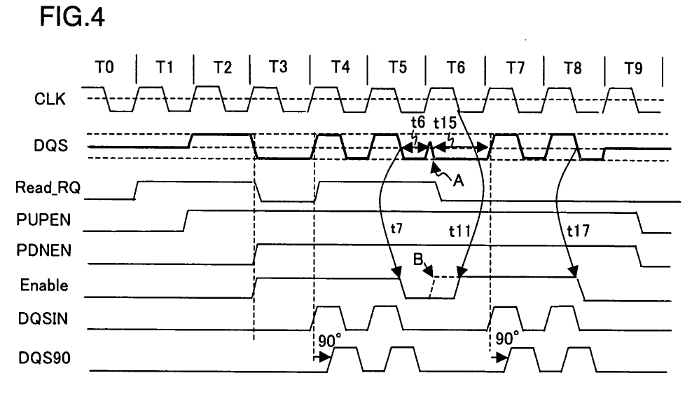

Next, an operation timing in the control circuit 14 as operated above will be explained. FIG. 4 is a timing chart showing an operation timing of the memory read control circuit according to the second example of the present invention. FIG. 4 shows the operation timing in which the interval between the read operations or the interval from the write to the read is at minimum, one clock, and the postamble and preamble of the data strobe signal DQS are consecutive. As for the operation up to the cycle T5 the explanation is omitted because it is the same as FIG. 2, except that two read requirement signals Read_RQs come consecutively.

In FIG. 4, the level of the data strobe signal DQS is detected at the timing t11 which is an edge of the second clock signal CLK seen from the edge of the end of the last data strobe signal DQS in the burst of the first read operation (the change of the mask signal Enable to L-level at the timing t7, that is, at the beginning of the postamble). If the detect level is L-level, it is judged whether the preamble of the read is already started, followed by controlling the mask signal Enable being controlled to H-level. The burst count operation in the data strobe signal DQS and the operations thereafter are then performed like in FIG. 2. On the other hand, if the detected level is H-level, since it is the pull-up state, and the preamble of the read is not started yet, the operation to detect the preamble of the data strobe signal DQS and the operations thereafter are started, like the operations after the T2 cycle in FIG. 1.

In FIG. 4, at a point A which is a border between the postamble and preamble of the data strobe signal, a glitch is generated in the data strobe signal DQS. Since the mask signal Enable is in the L-level state, however, this glitch is not propagated from the delay circuit 16 into the inside, thereby preventing an error operation.

When the interval of the read operations is at minimum, one clock, unless the mask signal Enable is controlled by detecting the level of the data strobe signal DQS at the timing t11, the mask signal Enable assumes an error operation state as shown at a point B. In this case, there is possibility that the data strobe signal DQS including the glitch is supplied to the delay circuit 16. Example 1 is effective if the interval between the read operations is long enough. If the interval between the read operations at minimum, one clock, and it is not possible to secure the pull-up period to detect the preamble of the data strobe signal DQS, however, there is possibility of an error operation. On the other hand, according to the control method of Example 2, it is possible to prevent the error operation even if the interval between the read operations is at minimum, one clock.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A memory read control circuit comprising:
a pull-up circuit that pulls-up an input terminal which inputs a data strobe signal output from a memory;
a comparator circuit that compares a signal level of said data strobe signal with a predetermined reference voltage;
a mask circuit that masks an output signal which is a comparison result of said comparator circuit with a mask signal;
a delay circuit that delays the output signal of said mask circuit and generating the data strobe signal having a timing to receive data output from said memory; and
a control circuit that receives a read requirement signal to require a data read from said memory and a burst length information signal indicating the length of a burst for the read requirement, wherein said control circuit controls said pull-up circuit so as to pull-up said data strobe signal to a first level if the read requirement signal is active, makes said mask signal to an unmask state if said data strobe signal is transferred from the first level to a second level, and makes said mask signal to a mask state if a repetition of a predetermined transfer of said data strobe signal is detected based on said burst length information signal.

2. The memory read control circuit according to claim 1,
wherein a postamble of said data strobe signal is started upon the repetition of said predetermined transfer of said data strobe signal; and
said control circuit finishes a control to pull-up said data strobe signal to the first level after a period of the postamble is finished.

3. The memory read control circuit according to claim 2,
further comprising a pull-down circuit that pulls-down said input terminal;
wherein the control circuit controls said pull-down circuit so as to let said pull-down circuit operate if said data strobe signal is transferred from the first level to the second level and so as to make said pull-down circuit inoperative synchronously with the end of said control to pull-up said data strobe signal to the first level.

4. The memory read control circuit according to claim 1,
wherein said control circuit makes said mask signal to the mask state if a new read requirement signal is consecutively input at a predetermined interval following said read requirement signal, and thereafter makes said mask signal to the unmask state again at a predetermined interval.

5. The memory read control circuit according to claim 4,
wherein said predetermined interval corresponds to one clock cycle in a standard clock signal by which said control circuit is operated.

6. A method for controlling a memory read control circuit comprising:
providing a memory read control circuit comprising a pull-up circuit for pulling-up an input terminal to input a data strobe signal output from a memory, a comparator circuit for comparing a signal level of said data strobe signal with a predetermined reference voltage, a mask circuit for masking an output signal which is the comparison result of said comparator circuit with a mask signal, and a delay circuit for delaying the output signal of said mask circuit and generating the data strobe signal having a timing to receive data output from said memory;
pulling-up said data strobe signal to a first level if a read requirement signal to require a data read from said memory is active;
detecting a transfer of said data strobe signal from the first level to a second level;
making said mask signal to an unmask state if said data strobe signal is transferred to said second level;
detecting a repetition of a predetermined transfer of said data strobe signal based on a burst length information signal to be input; and
making said mask signal to a mask state if said data strobe signal repeats said predetermined transfer.

7. The method according to claim 6, further comprising:
starting a postamble in said data strobe signal by repeating the predetermined transfer of said data strobe signal, and
finishing the control to pull-up said data strobe signal to the first level after the end of the postamble period.

8. The method according to claim 7, wherein
said memory read control circuit further comprises a pull-down circuit; and wherein
the method further comprises:
operating said pull-down circuit to pull-down said input terminal if the transfer of said data strobe signal from the first level to the second level is detected; and
finishing the control to pull-up said data strobe signal to the first level and synchronously stopping the operation of said pull-down circuit.

9. The method according to claim 6, further comprising:
judging whether or not a new read requirement signal is consecutively input at a predetermined interval after the input of said read requirement signal;
judging whether or not said data strobe signal is in the second level when the predetermined interval passes after the step of making said mask signal to the mask state if the new read requirement signal is consecutively input at the predetermined interval after the input of said read requirement signal; and
making said mask signal to the unmask state again if said data strobe signal is in the second level.
